(19) United States
(12) Patent Application Publication
(10) Pub. No.: US 2012/0227808 A1
(43) Pub. Date: Sep. 13, 2012

(54) PROCESS FOR PRODUCTION OF SILICON POWDER, MULTI-CRYSTAL-TYPE SOLAR CELL PANEL, AND PROCESS FOR PRODUCTION OF THE SOLAR CELL PANEL

(75) Inventors: Ichiro Nakayama, Osaka (JP); Hitoshi Yamanishi, Osaka (JP); Yoshihisa Ooido, Osaka (JP); Nobuyuki Kamikihara, Nara (JP); Tomohiro Okumura, Osaka (JP)

(73) Assignee: PANASONIC CORPORATION, Osaka (JP)

(21) Appl. No.: 13/503,066

(22) PCT Filed: Oct. 19, 2010
(86) PCT No.: PCT/JP2010/006194

§ 371 Date: Apr. 20, 2012

(30) Foreign Application Priority Data
Oct. 23, 2009 (JP) 2009-244623
Dec. 25, 2009 (JP) 2009-294153
Dec. 25, 2009 (JP) 2009-294154

(51) Int. Cl. H01L 31/0368; B02C 19/00

(52) U.S. Cl. 136/258; 241/29; 438/97; 257/E31.043

(57) ABSTRACT

Disclosed is a process for producing a silicon powder, which comprises the steps of: powderizing a silicon ingot having a grade of 99.999% or more into a crude silicon powder having a particle diameter of 3 mm or less by means of high-pressure purified-water cutting; and reducing the crude silicon powder into a silicon powder having a particle diameter ranging from 0.01 to 10 [mu]m inclusive by means of at least one method selected from jet milling, wet granulation, ultrasonic wave disruption and shock wave disruption. The process is a technique for producing a silicon powder rapidly from a silicon ingot without reducing purity.

### TECHNICAL FIELD

The present invention relates to a method of producing silicon powder, and a polycrystalline solar cell panel manufactured with the silicon powder.

### BACKGROUND ART

Crystalline solar cells may be categorized mainly into mono crystalline solar cells and polycrystalline solar cells. Generally, a crystalline solar cell uses a sliced ingot as a silicon wafer that constitutes a main body of the solar cell, the sliced ingot being made by cutting N- or P-type doped silicon ingot 30 into slices having a thickness of about 200 μm, by using wire 31 or by using a dicing technique, as shown in FIG. 1. Silicon ingot 30 may be a mono crystalline silicon ingot made by, for example, the Czochralski process, or may be a polycrystalline silicon ingot made by melting a silicon cast and then solidifying the molten silicon by the casting method.

In order to cut a silicon ingot with a wire, usually, ingot 30 is cut with wire 31 while being ground with abrasive grains. However, in order to make a cut wafer thinner, further improvements have been devised (see, e.g. Patent Literature 1). For example, in Patent Literature 1, a technique is reported in which silicon ingot 30 immersed in electrically insulating liquid is cut by electrical discharge machining with wire 31, which is a brass wire having a diameter of about 0.2 mm. Here, an improvement is also suggested in which silicon ingot is cut concurrently in multiple places using multiple wires placed around the silicon ingot in parallel. However, even when the technique described in Patent Literature 1 is used, it is still difficult to obtain a wafer having a thickness of 100 μm or less. Further, when silicon is cut with a wire, breakages may occur near the wafer surface. When wet treatment is performed using chemicals in order to repair the breakage, there may be a bad influence on the power generation efficiency of a solar cell.

Further, as a method of making a silicon substrate for a polycrystalline solar cell, a method is known in which, silicon particles deposited on a support substrate are molten and multi-crystallized (see Patent Literature 2). FIG. 2 shows an apparatus for deposing a polycrystalline silicon film. Arc discharge 41 is applied to silicon anode 40 to produce silicon particles 42 (20 nm or less); produced silicon particles 42 are carried on argon gas 43 and are deposited on support substrate 45a via transport tube 44; silicon particles 42 deposited on support substrate 45 are molten by exposure with high temperature plasma 46; molten silicon particles 42 are annealed using halogen lamp 47 to form a polycrystalline silicon plate; and in separation chamber 48, support substrate 45 and polycrystalline silicon plate 49 are separated from each other.

Further, as a method of making a silicon substrate for a polycrystalline solar cell, a method is known in which, silicon powder having an average particle size of 10 μm is deposited on a carbon substrate by plasma spraying, and then light from a halogen lamp is focused on a surface of the deposited silicon film to melt, solidify, and crystallize the silicon film (see e.g. Patent Literature 3). In Patent Literature 3, silicon powder is made by mechanically pulverizing a silicon ingot using, for example, the ultrasonic disruption method.

Further, a method is also known in which silicon powder with high purity is formed by pulverizing a silicon ingot using rollers (see e.g. Patent Literature 4).

Further, a method is known in which an amorphous silicon layer is annealed using plasma to form multi-crystal silicon (see e.g. Patent Literature 5).

### CITATION LIST

### Patent Literature

### PTL 1

Japanese Patent Application Laid-Open No. 2000-263545

### PTL 2

Japanese Patent Application Laid-Open No. 6-268242

### PTL 3

Japanese Patent Application Laid-Open No. 2000-279841

### PTL 4

Japanese Patent Application Laid-Open No. 57-067019

### PTL 5

Japanese Patent Application Laid-Open No. 06-333953

### SUMMARY OF INVENTION

### Technical Problem

As described above, various techniques for making a crystalline silicon film or a crystalline silicon plate for manufacturing polycrystalline solar cells are discussed. However, in order to reduce the production cost of crystalline solar cells, it is important to further reduce the making cost of silicon substrates or silicon films.

Regarding general silicon ingots, a mono crystalline silicon ingot has a diameter of 300 mm and a polycrystalline silicon ingot, although its shape is different from the mono crystalline silicon ingot, has nearly the same diameter as the mono crystalline silicon ingot. For this reason, it is difficult to make a silicon substrate or a silicon film that has a large-area surface.

Thus, according to the present invention, a method has been studied in which a silicon ingot is pulverized into silicon powder and the obtained silicon powder is used as a silicon raw material for a crystalline solar cell. The purity of a silicon substrate or a silicon film for a solar cell needs to meet the standard of solar-grade silicon (SOG-Si, normally 99.999% or more). However, it has been difficult to pulverize a silicon ingot into powder that meets the standard of solar-grade silicon at low cost without lowering the purity.

That is, generally, the pulverization of a silicon ingot is performed using a pulverizer or a roller. However, during pulverizing, impurities from materials of the pulverizer or rolls, in particular metal materials, contaminates pulverized powder of a silicon ingot. For this reason, even when a silicon ingot that meets the standard of solar-grade silicon is pulverized, silicon powder that meets the standard of solar-grade silicon cannot be produced.

It may be possible to produce silicon particles with high purity by applying electrical arc to silicon anode as described in above Patent Literature 2, however, it is difficult to control the size of the silicon powder. Accordingly, it is difficult to improve characteristics of a solar cell. And therefore, in order to deposit silicon powder on the substrate surface in a uniform and homogeneous manner, large-scale producing equipment is required.

Further, a method of pulverizing a silicon ingot using a method such as ultrasonic disruption as shown in Patent Literature 3 requires enormous time to obtain silicon particles having the desired particle size (0.1 to 10 μm).

It is therefore an object of the present invention to provide a technique for rapidly obtaining silicon powder from a silicon ingot without lowering the purity.

Further, in order to dope a crystalline silicon film with a dopant to form a P-N junction, the dopant needs to be introduced either by depositing a dopant-containing substance (typically, glass) on the crystalline silicon film to thermally diffuse the substance, and then removing the substance; or by depositing the crystalline silicon film under a dopant-containing gas atmosphere. These techniques may increase the number of making steps and thus requires long time, may require the use of highly hazardous gas, or may make it difficult to control the concentration of a dopant to be introduced in a silicon film or control the depth to which a dopant is introduced.

Therefore, the present invention provides a technique for easily forming a polycrystalline silicon film having a P-N junction rapidly. Further, by this means, the present invention provides a solar cell panel that can be made at low cost.

### Solution to Problem

A first aspect of the present invention relates to a method of producing silicon powder by pulverizing a silicon ingot.

[1] A method of producing silicon powder, comprising:

pulverizing by high pressure pure water cutting a silicon ingot having a purity of 99.999% or more into coarse silicon powder having a particle size of 3 mm or less; and

pulverizing the coarse silicon powder into silicon powder having a particle size of 0.01 to 10 μm by at least one method selected from jet milling, wet atomization, ultrasonic disruption, and shock wave disruption.

A second aspect of the present invention relates to a method of manufacturing a solar cell panel using the silicon powder.

[2] A method of manufacturing a polycrystalline solar cell panel, comprising:

forming a silicon powder layer by applying on the substrate the silicon powder obtained by the method according to [1]; and

forming a polycrystalline silicon film by sweeping plasma on a surface of the silicon powder layer to melt, and by recrystallizing the melted silicon powder layer.

[3] The method of manufacturing a polycrystalline solar cell panel according to [2], wherein the step of applying the silicon powder on the substrate is performed with at least one method selected from squeegee application, die coating, ink-jet application, or dispenser application.

[4] The method of manufacturing a polycrystalline solar cell panel according to [2] or [3], wherein the substrate contains at least one of Al, Ag, Cu, Sn, Zn, In, and Fe.

[5] The method of manufacturing a polycrystalline solar cell panel according to any one of [2] to [4], wherein the plasma is atmospheric pressure plasma.

[6] The method of manufacturing a polycrystalline solar cell panel according to any one of [2] to [5], wherein a rate of the sweeping is 100 to 2,000 mm/sec.

[7] The method of manufacturing a polycrystalline solar cell panel according to any one of [2] to [6], wherein the silicon powder is P-type silicon powder containing boron.

[8] The method of manufacturing a polycrystalline solar cell panel according to [7], further comprising:

arranging the substrate on which the polycrystalline silicon film is formed in a plasma reaction chamber; and

introducing gas containing phosphorus or arsenic into the plasma reaction chamber so as to convert the gas into plasma and to form a P-N junction by doping a surface layer of a P-type polycrystalline silicon film containing the boron into N-type.

[9] The method of manufacturing a polycrystalline solar cell panel according to [7], further comprising:

arranging the substrate on which the polycrystalline silicon film is formed in a plasma reaction chamber; and

disposing a solid material containing phosphorus or arsenic in the reaction chamber and irradiating the solid material with plasma generated by introducing inert gas so as to form a P-N junction by doping a surface layer of a P-type polycrystalline silicon film containing the boron into N-type.

[10] The method of manufacturing a polycrystalline solar cell panel according to any one of [2] to [6], wherein the silicon powder is N-type silicon powder containing phosphorus or arsenic.

[11] The method of manufacturing a polycrystalline solar cell panel according to [10], wherein a polycrystalline silicon film having a P-N junction is formed by sweeping plasma containing boron particles on a surface of a N-type silicon powder layer applied on the substrate.

[12] The method of manufacturing a polycrystalline solar cell panel according to any one of [2] to [6], wherein

the step of forming the silicon powder layer comprises:

forming a N-type silicon powder layer on the substrate by applying N-type silicon powder containing phosphorus or arsenic; and

forming a P-type silicon powder layer by applying P-type silicon powder containing boron on the N-type silicon powder layer.

### Advantageous Effects of Invention

According to the present invention, it is possible to produce silicon powder efficiently at low cost from a silicon ingot with high purity, without lowering the purity. Further, by combining a technique for applying silicon powder and a technique for melting and crystallizing the applied silicon powder, it is possible to make the silicon powder applied on a substrate having a large-area surface into a polycrystalline silicon film.

Further, according to the present invention, it is possible to form a polycrystalline silicon film having a P-N junction, thus making it possible to manufacture a P-N junction solar cell panel having a large-area surface, easily and rapidly.

### BRIEF DESCRIPTION OF DRAWINGS

FIG. 1 shows cutting a silicon ingot with a wire;

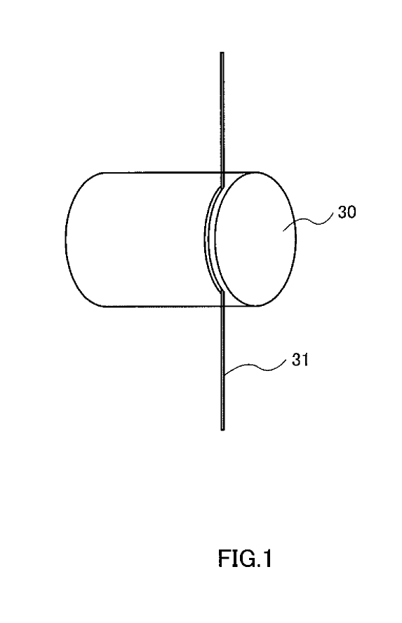

FIG. 2 shows an overview of an apparatus for producing a polycrystalline silicon plate;

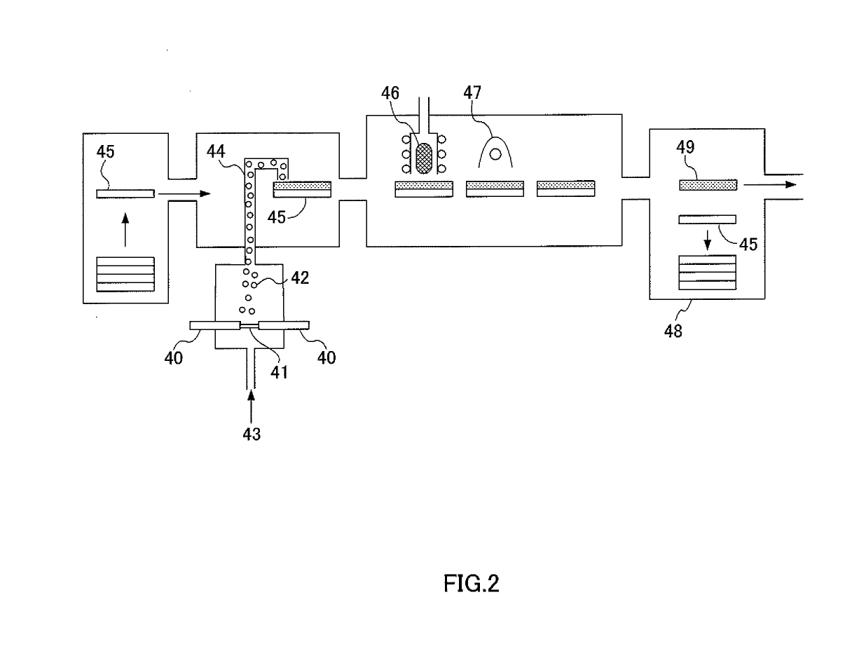

FIGS. 3A to 3C show a flowchart for producing desired silicon powder from a silicon ingot;

FIG. 4 is a schematic view of an atmospheric pressure plasma apparatus used to form a polycrystalline silicon film from a silicon powder coat;

FIGS. 5A to 5E show a flow chart for manufacturing a solar cell panel of Embodiment 1;

FIGS. 6A to 6D show a flow chart for manufacturing a solar cell panel of Embodiment 2;

FIG. 7 is a schematic view of an plasma apparatus used in Embodiment 2; and

FIGS. 8A to 8D show a flow chart for manufacturing a solar cell panel of Embodiment 3.

### DESCRIPTION OF EMBODIMENTS

1. Method of Producing Silicon Powder

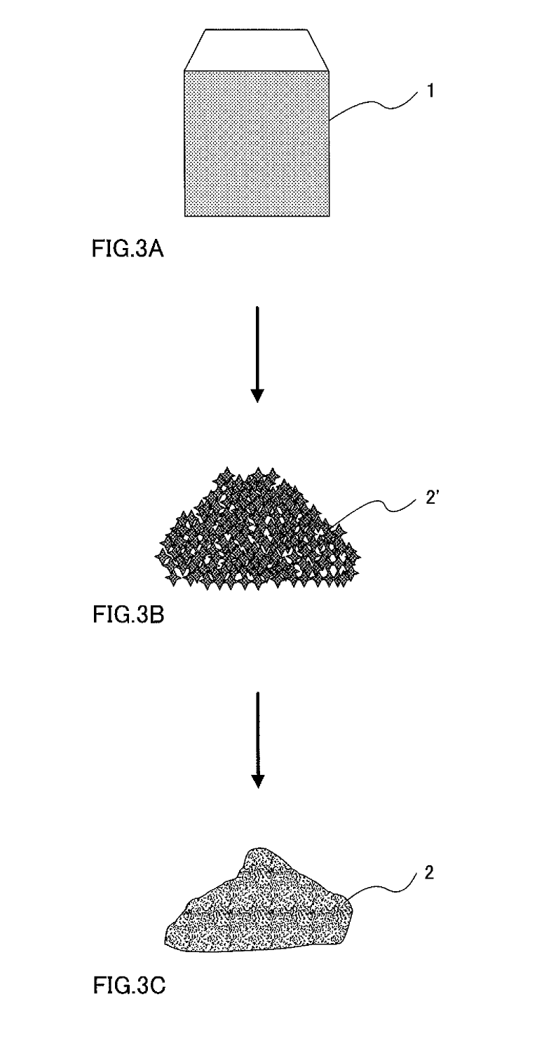

The first aspect of the present invention is a method of producing silicon powder by pulverizing a silicon ingot. FIGS. 3A to 3C show a flowchart for making silicon powder 2 from silicon ingot 1.

First, silicon ingot 1 to be pulverized is preferably an ingot that meets the standard of solar-grade silicon. The ingot that meets the standard of solar-grade silicon refers to an ingot having a silicon purity of 99.99 wt % or more, preferably 99.999 wt % or more, more preferably 99.9999 wt % or more.

Silicon ingot 1 to be pulverized is N- or P-type doped. In order to dope silicon ingot 1 into N-type, arsenic or phosphorus may be diffused into the ingot. On the other hand, in order to dope silicon ingot 1 into P-type, boron (B) may be diffused into the ingot.

A feature of the present invention lies in that a silicon ingot is pulverized rapidly without lowering its purity. Specifically, a feature of the present invention lies in that silicon ingot 1 is pulverized in the following two steps. By performing pulverization in two or more steps, the ingot can be pulverized within a shorter time compared to when the ingot is directly pulverized into a desired particle size.

A first pulverizing step is to pulverize silicon ingot 1 into coarse silicon powder 2′ having a particle size of about 3 mm or less, preferably 1 mm or less, by ultrahigh pressure water cutting (see FIG. 3B). Ultrahigh pressure water cutting is a technique for cutting materials using the collision energy of ultrahigh pressure water. Ultrahigh pressure water may be water having a water pressure of about 300 MPa. Ultrahigh pressure water cutting can be performed using an ultrahigh pressure water cutter from Sugino Machine Limited, for example. Further, water used for ultrahigh pressure water cutting is preferably ultrapure water having a specific resistance of 18 MΩ·cm, which is as high as the resistance used in semiconductor manufacturing processes.

A second pulverizing step is to pulverize obtained coarse silicon powder 2′ into silicon powder 2 having a particle size of 0.01 to 10 μm, preferably a particle size of 0.03 μm to 3 μm, by the wet atomization method using, for example, STAR BURST apparatus from Sugino Machine Limited, by jet milling, by ultrasonic disruption, or by shock wave disruption.

Wet atomization is a wet atomization system in which: a pressurizing liquid containing dispersed with pulverized products is applied with the pressure as ultrahigh as 245 MPa; the pressurizing liquid applied with the pressure is divided into two channels; and then the two divided pressurizing liquid are merge into a single channel so as to make the pulverized products collide at the site where the channels are merged. Since the wet atomization is a pulverizing method without using a pulverizing medium, as is the case with jet milling, ultrasonic disruption, or shock wave disruption, it is possible to prevent contamination by impurities.

The particle size of silicon powder 2 according to the present invention is set by taking into consideration, for example, time for melting particles as well as the capacity of a pulverizing facility, and production time in mass production. When the particle size of silicon powder 2 is 10 μm or less, the melting temperature of silicon can be lowered. Because the melting temperature of typical silicon is 1410° C., a large-scale furnace is required to melt silicon. However, when the particle size of silicon powder is 10 μm or less, the melting point lowers. For example, when the particle size is 10 μm or less, the melting point of silicon may be lowered to about 800° C. On the other hand, when the particle size of silicon powder is over 10 μm, the contact area between particles is not sufficient so that heat transfer is not increased and the melting point does not lower sufficiently.

As described later, silicon powder 2 according to the present invention is applied on a substrate, is molten by atmospheric pressure plasma, and is further cooled for recrystallization. It is experimentally found out that in order to reduce a total production time including time for melting silicon particles by atmospheric pressure plasma, time for recrystallizing the molten silicon, setting the particle size at 10 μm or less is preferable.

The size of the lower limit of silicon powder 2 is in particular not limited, but taking into consideration the capacity of a pulverizing apparatus and mechanical ability to melt silicon powder, the lower limit only needs to be 0.01 μm or more.

According to the present invention, it is possible to obtain silicon powder without allowing impurities that deteriorate the characteristics of solar cell, such as Al, Fe, Cr, Ca, and K, to contaminate the silicon powder. That is, silicon ingot 1 can be pulverized while maintaining the purity of silicon. Therefore, when the purity of silicon ingot 1 can be 99.99% or more (preferably, 99.9999% or more), the purity of silicon powder to be obtained will be 99.99% or more (preferably, 99.9999% or more).

2. Method of Producing Solar Cell Panel

The second aspect of the present invention is to manufacture a solar cell panel using the silicon powder produced by the above-described method. Hereinafter, the method of producing a solar cell panel according to the present invention using silicon powder according to the present invention will be described.

The method of producing a solar cell panel of the present invention includes 1) a first step of forming a silicon powder layer by applying silicon powder on the surface of a substrate which constitutes an electrode of the solar cell, and 2) a second step of forming a polycrystalline silicon film by sweeping plasma on the surface of the silicon powder layer on the substrate. Each step will be described below.

1) In the first step, silicon powder according to the present invention is evenly applied over the surface of a substrate, which later constitutes an electrode of a solar cell, to form a silicon powder layer.

The substrate is in particular not limited, and it only needs to be a metal substrate or a roll that is made of, for example, Al, Ag, Cu, and Fe, and that is used as a rear surface electrode of the solar cell. Further, substrate 3 may be a transparent substrate with high conductivity containing Sn, Zn, and In. When a transparent substrate is used, it is possible to stack multiple solar cells.

Regarding the application of silicon powder, dried silicon powder may be applied using a squeegee, or ink obtained by dispersing silicon powder into a medium may be applied by spin coating, die coating, ink jet or a dispenser. The ink can be obtained by dispersing silicon powder into, for example, alcohol. Ink containing silicon powder can be obtained by referring to, for example, Japanese Patent Application Laid-Open No. 2004-318165.

The amount of silicon powder to be applied on the substrate needs to be precisely adjusted, and specifically, it is preferable to set the amount at about 2 to 112 g/cm². However, some concave and convex portions in the surface of the silicon powder layer formed on the substrate can be acceptable. This is because the silicon powder is molten so that the silicon powder layer is smoothened, as described later.

2) In the second step, a polycrystalline silicon film is formed by melting the silicon powder layer by sweeping plasma on the surface of the silicon powder layer on the substrate, and recrystallizing the molten silicon powder layer.

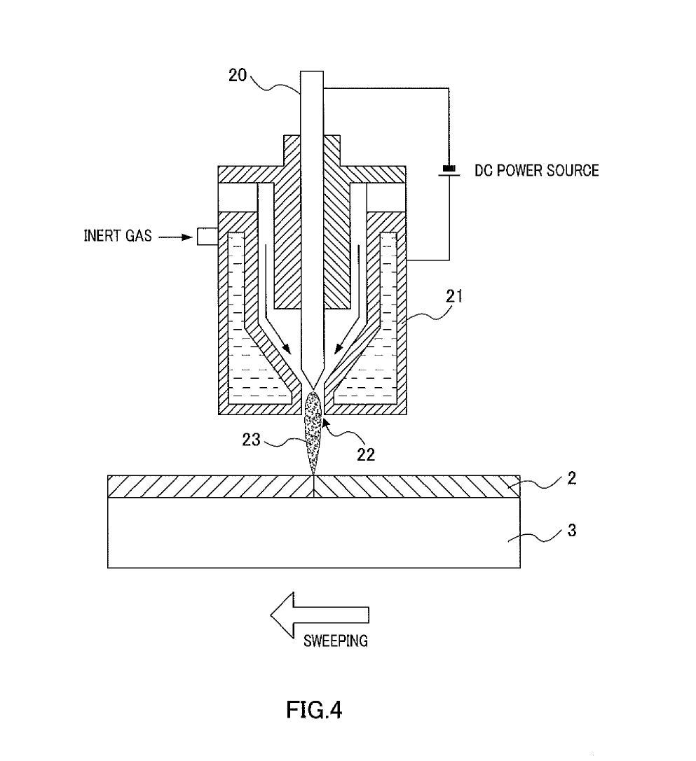

The type of plasma to be swept on the surface of the silicon powder layer is not limited, with an example being atmospheric pressure plasma. An overview of an atmospheric pressure plasma apparatus is shown in FIG. 4. As shown in FIG. 4, the atmospheric pressure plasma apparatus includes cathode 20 and anode 21. In anode 21, plasma jet nozzle 22 is provided. Because applying DC voltage between cathode 20 and anode 21 generates arc discharge, flowing inert gas (for example, nitrogen gas) allows plasma 23 to jet from plasma jet nozzle 22. Such an atmospheric pressure plasma apparatus is described in, for example, Japanese Patent Application Laid-Open No. 2008-53632.

The substrate coated with silicon powder is loaded on a stage that is movable along the XYZ axes of the above apparatus, and heat processing is performed on the surface of substrate 3 by sweeping across substrate 3 using the atmospheric pressure plasma source. The temperature of the atmospheric pressure plasma is typically 10,000° C. or more, but the temperature of the tip end of plasma jet nozzle 22 is adjusted to about 2,000° C. Plasma jet nozzle 22 is arranged about 5 mm apart from the silicon powder on the substrate. Plasma 23 is assisted with nitrogen gas to be injected to the substrate surface, with an input power of 20 kw. Plasma 23 from jet nozzle 22 is applied to a 40 mm-diameter area on the substrate surface. The silicon powder on the area on which plasma 23 has been applied will melt.

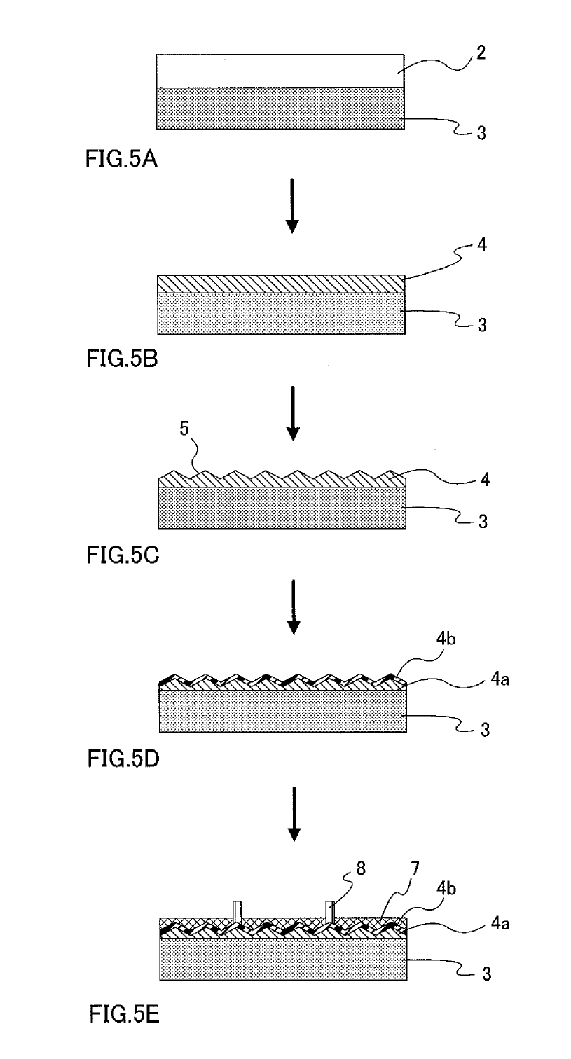

The sweeping rate is preferably 100 mm/sec to 2,000 mm/sec, with an example being about 1,000 mm/sec. When the sweeping rate is 100 mm/sec or less, substrate 3 as a base will melt, which may adversely affect polycrystalline silicon film 4 to be formed (see FIG. 5). Further, when the sweeping rate is 2,000 mm or more, only the upper portion of silicon particle 2 will be molten. Further, sweeping at a rate of 2,000 mm/sec or more requires a large-scale apparatus system.

A trace amount of hydrogen gas may be mixed into inert gas for assisting plasma. By mixing a trace amount of hydrogen into the inert gas, an oxide film of the surface of a silicon particle can be removed, and a polycrystalline silicon film with less crystal defects can be obtained.

The temperature on the substrate surface of atmospheric pressure plasma 23 can be selectively controlled by adjusting, for example, the power of the atmospheric pressure power source and the interval between jet nozzle 22 and the substrate. The condition for melting silicon powder is adjusted by appropriately controlling the temperature on the substrate surface of atmospheric pressure plasma 23.

After the silicon powder has been molten, the silicon can be multi-crystallized by further applying inert gas (e.g. nitrogen gas) to cool the molten silicon powder. By this means, a polycrystalline silicon film is formed on the surface of the substrate. At this time, when the molten silicon powder is rapidly cooled, polycrystalline silicon having a small crystalline particle size can be obtained. For this reason, it is preferable to cool the molten silicon powder as rapidly as possible so that polycrystalline silicon having a crystalline particle size of 0.05 nm or less can be obtained.

In this way, because the present invention uses silicon powder for silicon layer to be arranged on the substrate, unlike the normal procedure for melting bulk silicon, silicon can be molten using atmospheric pressure plasma 23. For this reason, the silicon powder arranged on the substrate having a large-area surface can be molten and recrystallized.

As described above, a feature of the present invention lies in that a P-N junction is easily formed on a polycrystalline silicon film rapidly. A method of forming a P-N junction will be described in detail in the embodiments below.

### Embodiment 1

Embodiment 1 describes an embodiment where a P-N junction is formed by performing plasma doping after formation of a polycrystalline silicon film.

FIGS. 5A to 5E show a flow chart for producing a solar cell panel of Embodiment 1. As shown in FIGS. 5A to 5E, the method of producing a solar cell panel of Embodiment 1 includes: 1) a first step of forming silicon powder layer 2 (FIG. 5A), 2) a second step of forming polycrystalline silicon film 4 by melting the silicon powder layer by sweeping plasma on the surface of the silicon powder layer, and then recrystallizing the molten silicon powder layer (FIG. 5B), 3) a third step of texturing the surface of polycrystalline silicon film 4 (texturing) (see FIG. 5C), 4) a fourth step of forming a P-N junction on the polycrystalline silicon film 4 by doping the surface layer on the polycrystalline silicon film (see FIG. 5D), and 5) a fifth step of forming insulating film 7 on the surface of the surface layer of polycrystalline silicon film 4 (see FIG. 5E).

In the third step, a procedure for texturing the surface of polycrystalline silicon film 4 is in particular not limited, and texturing with acid or alkali (e.g. KOH) or gas plasma treatment using, for example, chlorine trifluoride gas (ClF₃) or sulfur hexafluoride (SF₆) may be employed. Specific textured structure 5 is in particular not limited, and any known structure can be used. Generally, forming textured structure 5 on the light-incidence surface of the silicon film of the solar cell prevents reflection on the light-incidence surface.

In the fourth step, surface layer 4b of the polycrystalline silicon film is doped. The types of a dopant may be selected depending on whether the polycrystalline silicon film is N- or P-type doped. For example, when the polycrystalline silicon film is N-type doped, using boron as a dopant can allow a P-N junction to be formed. On the other hand, when the polycrystalline silicon film is P-type doped, using phosphorus or arsenic as a dopant can allow a P-N junction to be formed.

A feature of the present embodiment lies in that doping is performed by irradiation of plasma. In order to perform doping using plasma, it is only necessary to dope surface layer 4b of polycrystalline silicon film 4 with a dopant, for example: by converting dopant-containing gas into plasma and applying the plasma on surface layer 4b of polycrystalline silicon film 4; or by converting inert gas into plasma under the presence of a dopant-containing solid material and applying the plasma on surface layer 4b of polycrystalline silicon film 4.

The method of converting dopant-containing gas into plasma to dope surface layer 4b of polycrystalline silicon film 4 with the dopant using the plasma is disclosed in, for example, Japanese Patent Application Laid-Open No. 2000-174287 and US Patent Application Publication No. 2004/0219723. Further, the method of converting inert gas into plasma under the presence of a dopant-containing solid material to dope surface layer 4b of polycrystalline silicon film 4 with the dopant using the plasma is disclosed in, for example, Japanese Patent Application Laid-Open No. 9-115851.

The step of doping the surface layer of polycrystalline silicon film by plasma may be performed after the second step but before the third step, or may be performed after the third step.

By doping surface layer 4b of polycrystalline silicon film using plasma in this way, polycrystalline silicon film 4 having N-type lower layer 4a and P-type surface layer 4b or polycrystalline silicon film 4 having P-type lower layer 4a and N-type surface layer 4b can be formed. By this means, a P-N junction can be formed in which the P-type area is in contact with the N-type area.

Further, in the step before doping surface layer 4b of polycrystalline silicon film 4 of substrate 3 with a dopant, surface layer 4b may be amorphized using inert gas. When surface layer 4b is amorphized, the amount of a dopant to be introduced can be made uniform.

Further, it is preferable that surface layer 4b of polycrystalline silicon film 4 doped with a dopant be heated rapidly to activate the introduced dopant. Generally, the semiconductor manufacturing process includes a step in which ion is implanted on the silicon surface and then amorphized silicon is returned to crystalline silicon using, for example, a lamp, rapidly. Using the same condition, the dopant can be activated. The activation can be performed using the rapid thermal annealing (RTA) technique using such as a flash lamp or laser. However, according to the present invention, it is preferable that activation be performed using the atmospheric pressure plasma that is used for converting coat of silicon powder 2 into polycrystalline film 4, in order to reduce the production cost and facility cost. That is, atmospheric pressure plasma is applied on surface layer 4b while sweeping the substrate. However, because the silicon film does not need to be completely molten, the atmospheric pressure plasma for activating surface layer 4b can have lower temperature than that used for melting silicon powder is applied.

The atmospheric pressure plasma used here is assisted by, for example, nitrogen gas, to be applied on the 40 mm-diameter area on the substrate surface with an input power of 20 kw. The plasma jet nozzle is arranged 15 mm apart from the substrate surface. The substrate is swept across the substrate at the rate of 1,000 mm/sec, and then is cooled by inert gas such as nitrogen gas to activate surface layer 4b of polycrystalline silicon film 4.

In the fifth step, insulating film 7 is further formed on the surface of surface layer 4b of polycrystalline silicon film 4 in order to prevent reflection and prevent deterioration of electrical characteristics of crystalline ends (FIG. 5E). Insulating film 7 may be, for example, a silicon nitride film, and may be formed by a sputtering method. Further, part of the surface of insulating film 7 is etched to form line-shaped electrode 8 in the etched part. Electrode 8 may be made of silver, for example.

### Embodiment 2

Embodiment 1 describes an embodiment where a P-N junction is formed by performing plasma doping after formation of a polycrystalline silicon film. Embodiment 2 describes an embodiment where melting and doping of the silicon powder layer is performed in the same step.

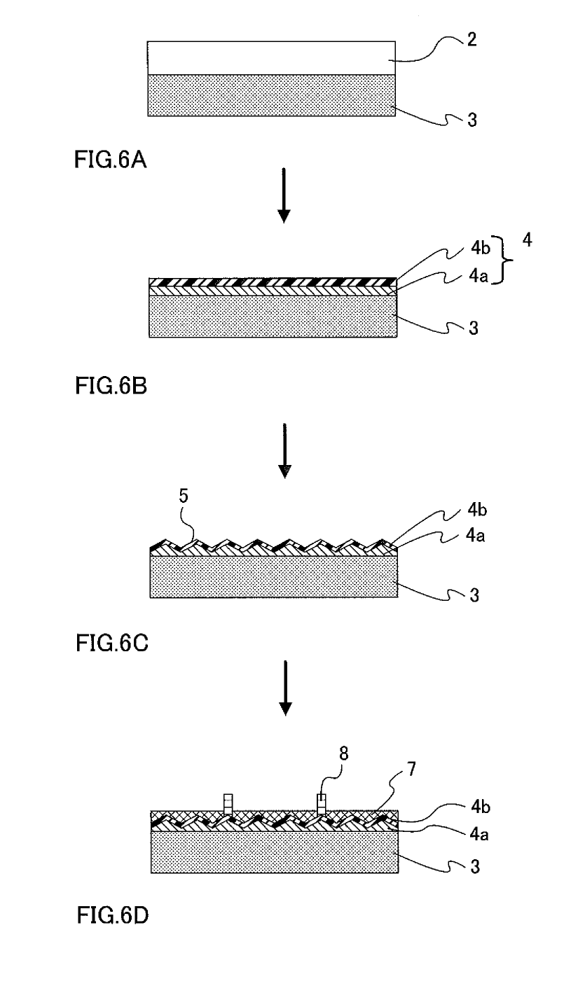

FIGS. 6A to 6D show a flow chart of a method for producing a solar cell panel of Embodiment 2. As shown in FIGS. 6A to 6D, the method of producing a solar cell panel of Embodiment 2 includes: 1) a first step of forming silicon powder layer 2 (FIG. 6A), 2) a second step of forming a polycrystalline silicon film by melting the silicon powder layer by sweeping plasma on the surface of the silicon powder layer, and then recrystallizing the molten silicon powder layer (FIG. 6B), 3) a third step of texturing the surface of polycrystalline silicon film 4 (texturing) (see FIG. 6C), and 4) a fourth step of forming insulating film 7 on the surface of surface layer 4b of polycrystalline silicon film 4 (see FIG. 6D).

A feature of the above present embodiment lies in that the step of melting silicon powder by plasma irradiation (the second step) and doping by plasma irradiation are performed at the same time. In order to melt silicon powder and dope the silicon powder by plasma at the same time, the surface of the silicon powder layer applied on the substrate may be swept by plasma having a dopant to melt the silicon powder.

The types of a dopant may be selected depending on whether the silicon powder applied in the first step is N- or P-type doped. For example, when the silicon powder is N-type doped, using boron as a dopant can allow a P-N junction to be formed. On the other hand, when the silicon powder is P-type doped, using phosphorus or arsenic as a dopant allow a P-N junction to be formed.

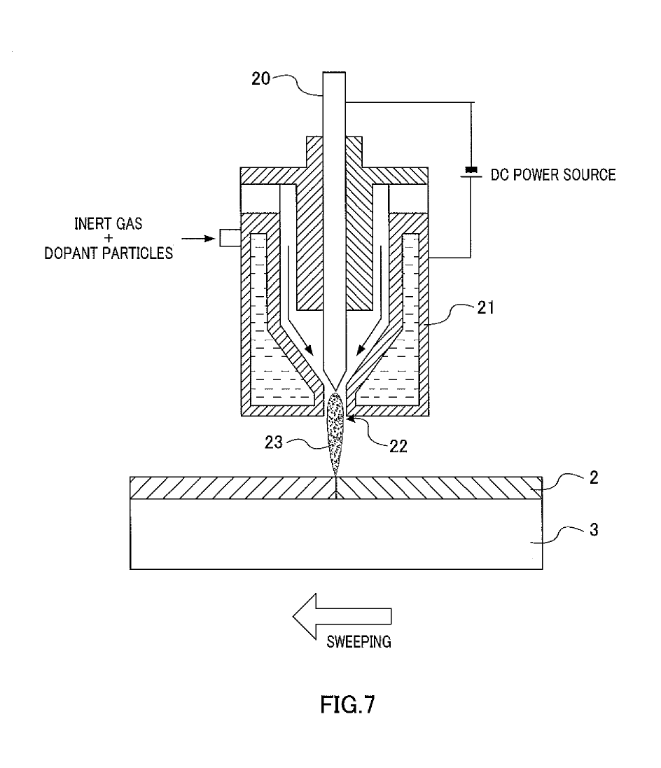

In order to introduce a dopant to plasma, solid particles of the dopant may be introduced into plasma. For example, as shown in FIG. 7, by flowing solid particles of a dopant along with inert gas between cathode 20 and anode 21 of the plasma apparatus, the solid particles of the dopant can be introduced to plasma. The apparatus shown in FIG. 7 can be obtained by modifying, for example, the apparatus disclosed in Japanese Patent Application Laid-Open No. 2008-53634, so that solid particles of a dopant can be introduced from the inlet for inert gas.

By sweeping the surface of the silicon powder layer by an atmospheric pressure plasma apparatus such as that shown in FIG. 7 in this way, the silicon powder layer can be molten and doped in the same step. By this means, polycrystalline silicon film 4 having N-type lower layer 4a and P-type surface layer 4b, or polycrystalline silicon film 4 having P-type lower layer 4a and N-type surface layer 4b can be formed in one step.

Further, according to the present embodiment, in the case where silicon powder is N-type doped in advance, it is preferable that boron be used as a dopant to be introduced to plasma. This is because using boron as a dopant allows safe and reliable doping.

On the other hand, when silicon powder is P-type doped in advance, phosphorus or arsenic particles needs to be used as a dopant. However, because phosphorus particles burn when being introduced to plasma, phosphorus particles cannot be diffused in the silicon powder layer. Further, use of arsenic particles is not preferable from the view point of safety.

### Embodiment 3

Embodiments 1 and 2 describe an embodiment where a P-N junction is formed by plasma doping. Embodiment 3 describes an embodiment where a P-N junction is formed by stacking layers of P-type doped silicon powder and N-type doped silicon powder.

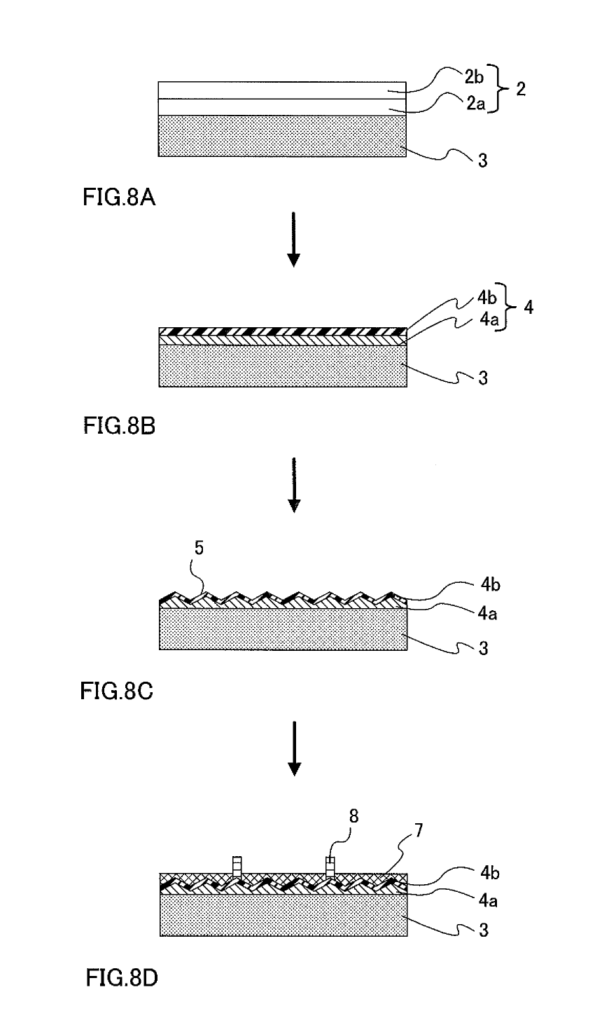

FIGS. 8A to 8D show a flow chart of the producing method of Embodiment 3. As shown in FIGS. 8A to 8D, the method of producing a solar cell panel of Embodiment 3 includes: 1) a first step of forming silicon powder layer 2 (see FIG. 8A), 2) a second step of forming polycrystalline silicon film 4 by melting the silicon powder layer by sweeping plasma on the surface of the silicon powder layer, and then recrystallizing the molten silicon powder layer (FIG. 8B), 3) a third step of texturing the surface of polycrystalline silicon film 4 (texturing) (see FIG. 8C), and 4) a fourth step of forming insulating film 7 on the surface of surface layer 4b of polycrystalline silicon film 4 (see FIG. 8D).

According to the present embodiment, the first step of forming silicon powder layer 2 includes a step of forming the layer of silicon powder 2a by applying N-type-doped silicon powder 2a on the substrate, and afterward a step of forming the layer of silicon powder 2b by applying P-type-doped silicon powder 2b on the layer of silicon powder 2a. That is, a feature of the present embodiment lies in that the silicon powder layer that is applied on the substrate includes a layer of N-type-doped silicon powder 2a as the lower layer and a layer of P-type-doped silicon powder 2b as the upper layer.

Further, the layer of N-type-doped silicon particles 2a and the layer of P-type-doped silicon powder 2b may be the same in thickness, and may be different in thickness depending on the purpose of use.

In this way, in the second step, the silicon powder layer having the layer of N-type-doped silicon powder 2a as the lower layer and the layer of P-type-doped silicon powder 2b as the upper layer is molten by sweeping plasma, and then the molten silicon powder layer is recrystallized. By this means, it is possible to form polycrystalline silicon film 4 having N-type lower layer 4a and P-type surface layer 4b.

The present embodiment describes the method of producing a solar cell panel including polycrystalline silicon film 4 having N-type lower layer 4a and P-type surface layer 4b, however, the N-type area and the P-type area can be positioned vice versa. That is, in the first step, P-type-doped silicon powder 2b may be first applied on the substrate to form the layer of silicon powder 2b, and then N-type-doped silicon powder 2a may be applied on the layer of silicon powder 2b to form the layer of silicon powder 2a.

### Experimental Example 1

Silicon powder having a particle size of about 1 μm is applied on a substrate (size: 370 mm (X axis)×470 mm (Y axis)). In Experimental Example 1, P-type silicon powder doped with boron is used. The silicon powder is applied using a squeegee to form a silicon powder coat having a thickness of about 30 μm.

Plasma is applied across the substrate by performing sweeping in the X axis direction using the atmospheric pressure plasma apparatus such as that shown in FIG. 4 to melt and recrystallize the silicon powder. The area to which plasma is applied is 40 mm in diameter. The inert gas for assisting plasma is nitrogen gas containing a trace amount of hydrogen gas.

After sweeping is completed across the substrate, the position is displaced in the Y axis direction by 40 mm apart from the original position and then plasma is applied again by performing sweeping in the X direction. This procedure is repeated to recrystallize all of the silicon powder arranged on the substrate in stripes, to obtain an almost homogeneous polycrystalline silicon film. The polycrystalline silicon film has a thickness of about 15 μm.

Next, the surface of the formed polycrystalline silicon film is textured (texturing) (see FIG. 5C). Then, the surface layer of the texture-processed P-type polycrystalline silicon film is N-type doped (see FIG. 5D).

In the present experimental example, the surface layer of P-type polycrystalline silicon film is doped with phosphorus (P) or arsine (arsenic, As) by plasma doping. Specifically, the surface layer of the polycrystalline silicon film can be doped with phosphorus (P) or arsenic (As) either by 1) converting gas containing phosphorus (P) or arsenic (As) into plasma so as to dope the surface layer of the polycrystalline silicon film with phosphorus (P) or arsenic (As), or by 2) converting inert gas into plasma under the presence of a solid material containing phosphorus (P) or arsenic (As), but the technique is not limited to these.

1) In order to perform doping using gas containing phosphorus (P) or arsenic (As), doping may be performed, for example, by introducing PH₄ gas (5%) diluted with He into a vacuum chamber in which the substrate is arranged and the pressure is kept at 1 Pa, plasma-degrading the introduced PH₄ by performing inductively coupled plasma (ICP) discharging at 13.56 MHz and 2,000 W, and applying the frequency as high as 500 KHz to the lower electrode of 50 W. When the size of substrate 3 is large, power needs to be generated in a large area. Therefore, it is preferable to employ the inductively coupled plasma (ICP) apparatus of dielectric division scheme using multi-spiral coils.

In this case, the plasma source is not limited to ICP, and a parallel plate electrode, an ECR, a helicon wave, a microwave, and DC discharge may be used. The lower electrode is not limited to the low frequency power source of 500 kHz, and power and DC may be applied using the frequency from 100 Hz to 13.56 MHz.

2) In order to perform doping using a solid containing phosphorus (P) or arsenic (As), discharging is performed for 30 seconds under the pressure of 20 Pa by arranging the parallel plate electrodes in a vacuum chamber, disposing the substrate that has a polycrystalline silicon film on one electrode and a solid material containing phosphorus (P) or arsenic (As) (for example, sintered material of phosphorus (P) or arsenic (As)) on the other electrode facing to the one electrode; applying the frequency as high as 13.56 MHz across the upper and lower electrodes; and introducing inert gas (for example, helium gas). The surface layer of the polycrystalline silicon film can be doped with a dopant by applying the power of 100 W to an electrode having the substrate thereon, and applying the power of 1,000 W on the counter electrode having a solid material containing phosphorus (P) or arsenic (As) (for example, a sintered material of phosphorus (P) or arsenic (As)) thereon.

Further, 2) in order to perform doping using a solid material containing phosphorus (P) or arsenic (As), the dopant may be introduced to the surface layer of the polycrystalline silicon film by disposing the solid material (for example, a sintered material) and the substrate having a multi-layer silicon film in a vacuum chamber; introducing inert gas to generate plasma using ICP, ECR, helicon wave, a microwave, or DC discharging; and mixing the dopant into the plasma.

Next, an insulating film is further formed on the surface of the polycrystalline silicon film in order to prevent reflection and prevent deterioration of electrical characteristics of crystalline ends (see FIG. 5E). Further, part of the surface of the insulating film is etched to form a line-shaped etched part, in which an electrode is to be provided.

The solar cell thus obtained yields 0.6 V open-circuit voltage (per 10 cm²), which is comparable to the data of the currently commercially available crystalline solar cell.

### Experimental Example 2

Experimental Example 1 describes an experimental example where silicon powder containing boron (B) is used. Experimental Example 2 describes an experimental example where silicon powder containing phosphorus (P) or arsenic (As) is used.

N-type-doped silicon powder having a particle size of about 1 μm is applied on a substrate. The silicon powder may be applied using a squeegee to form a silicon powder coat having a thickness of about 30 μm. Plasma introduced with boron particles is applied across the substrate while sweeping is performed in the X axis direction, using the atmospheric pressure plasma apparatus such as that shown in FIG. 7, so as to melt and recrystallize the silicon powder. The area to which plasma is applied is 40 mm in diameter. The inert gas for assisting plasma is nitrogen gas containing a trace amount of hydrogen gas.

At this time, boron particles are introduced in the atmospheric pressure plasma so as to melt the boron particles and to diffuse boron molecules near the surface of layer of silicon powder 2. The boron particle size preferably is 0.02 to 1 μm.

After sweeping in the X direction is completed across the substrate, the position is displaced in the Y axis direction by 40 mm apart from the original position and then plasma is applied again by performing sweeping in the X direction. This procedure is repeated in stripe order to recrystallize all of the silicon powder arranged on the substrate, to obtain an almost homogeneous polycrystalline silicon film. The polycrystalline silicon film has a thickness of about 15 μm. Boron is diffused in a depth of about 2 μm near the surface of the multi-crystallize silicon.

Next, the surface of the formed polycrystalline silicon film is textured (texturing). Then, an insulating film is formed on the surface layer of the polycrystalline silicon film. Further, part of the surface of the insulating film is etched to form a line-shaped etched part, in which an electrode is to be provided.

The solar cell thus obtained yields 0.6 V open-circuit voltage (per 10 cm²), which is comparable to the data of the currently commercially available crystalline solar cell.

### Experimental Example 3

Experimental Examples 1 and 2 describe an experimental example where a P-N junction is formed by plasma doping. Experimental Example 3 describes an experimental example where a P-N junction is formed by using P-type silicon powder and N-type silicon powder.

N-type silicon powder having a particle size of about 0.1 μm is applied on a substrate to form a layer of N-type silicon powder having a thickness of 15 μm. Next, P-type silicon powder having a particle size of about 0.1 μm is applied on the layer of the N-type silicon powder to form a layer of P-type silicon powder having a thickness of 15 μm.

Then, plasma is applied across the substrate by performing sweeping in the X axis direction using the atmospheric pressure plasma apparatus such as that shown in FIG. 4 to melt and recrystallize the P-type silicon powder and the N-type silicon powder. The area to which plasma is applied is 40 mm in diameter. The inert gas for assisting plasma is nitrogen gas containing a trace amount of hydrogen gas.

After sweeping in the X direction is completed across the substrate, the position is displaced in the Y axis direction by 40 mm apart from the original position and then plasma is applied again by performing sweeping in the X direction. This procedure is repeated in stripe order to recrystallize all of the silicon powder arranged on the substrate, to obtain an almost homogeneous polycrystalline silicon film. The polycrystalline silicon film has a thickness of about 15 μm.

Next, the surface of the formed polycrystalline silicon film 4 is textured (texturing). Next, an insulating film is further formed on the surface of the polycrystalline silicon film in order to prevent reflection and prevent deterioration of electrical characteristics of crystalline ends. Further, part of the surface of the insulating film is etched to form a line-shaped etched part, in which an electrode is to be provided.

The solar cell thus obtained yields 0.6 V open-circuit voltage (per 10 cm²), which is comparable to the data of the currently commercially available crystalline solar cell.

This application is entitled and claims the benefit of Japanese Patent Application No. 2009-244623, filed on Oct. 23, 2009, Japanese Patent Application No. 2009-294153, filed on Dec. 25, 2009, and Japanese Patent Application No. 2009-294154, filed on Dec. 25, 2009, the disclosure of each of which including the specification, drawings and abstract is incorporated herein by reference in its entirety.

### INDUSTRIAL APPLICABILITY

Silicon powder provided by the present invention can be used as a silicon raw material for a crystalline solar cell. Further, according to the present invention, it is possible to provide a solar cell panel having a large-area surface efficiently at low cost.

### REFERENCE SIGNS LIST

1 silicon ingot
2′ coarse silicon powder
2 silicon powder
3 substrate
4 polycrystalline silicon film
4a lower layer of polycrystalline silicon film
4b surface layer of polycrystalline silicon film
5 textured structure
7 insulating film
8 electrode
20 cathode
21 anode
22 plasma jet nozzle
23 plasma
30 ingot
31 wire
40 silicon anode
41 arc discharge
42 silicon particle
43 argon gas
44 transport tube
45 support substrate
46 high temperature plasma
47 halogen lamp
48 separation chamber
49 polycrystalline silicon plate

1. A method of producing silicon powder, comprising:
pulverizing by high pressure pure water cutting a silicon ingot having a purity of 99.999% or more into coarse silicon powder having a particle size of 3 mm or less; and
pulverizing the coarse silicon powder into silicon powder having a particle size of 0.01 to 10 μm by at least one method selected from jet milling, wet atomization, ultrasonic disruption, and shock wave disruption.

2. A method of manufacturing a polycrystalline solar cell panel, comprising:
forming a silicon powder layer by applying on the substrate the silicon powder obtained by the method according to claim 1; and
forming a polycrystalline silicon film by sweeping plasma on a surface of the silicon powder layer to melt, and by recrystallizing the melted silicon powder layer.

3. The method of manufacturing a polycrystalline solar cell panel according to claim 2, wherein the step of applying the silicon powder on the substrate is performed with at least one method selected from squeegee application, die coating, ink-jet application, or dispenser application.

4. The method of manufacturing a polycrystalline solar cell panel according to claim 2, wherein the substrate contains at least one of Al, Ag, Cu, Sn, Zn, In, and Fe.

5. The method of manufacturing a polycrystalline solar cell panel according to claim 2, wherein the plasma is atmospheric pressure plasma.

6. The method of manufacturing a polycrystalline solar cell panel according to claim 2, wherein a rate of the sweeping is 100 to 2,000 mm/sec.

7. The method of manufacturing a polycrystalline solar cell panel according to claim 2, wherein the silicon powder is P-type silicon powder containing boron.

8. The method of manufacturing a polycrystalline solar cell panel according to claim 7, further comprising:
arranging the substrate on which the polycrystalline silicon film is formed in a plasma reaction chamber; and
introducing gas containing phosphorus or arsenic into the plasma reaction chamber so as to convert the gas into plasma and to form a P-N junction by doping a surface layer of a P-type polycrystalline silicon film containing the boron into N-type.

9. The method of manufacturing a polycrystalline solar cell panel according to claim 7, further comprising:
arranging the substrate on which the polycrystalline silicon film is formed in a plasma reaction chamber; and
disposing a solid material containing phosphorus or arsenic in the reaction chamber and irradiating the solid material with plasma generated by introducing inert gas so as to form a P-N junction by doping a surface layer of a P-type polycrystalline silicon film containing the boron into N-type.

10. The method of manufacturing a polycrystalline solar cell panel according to claim 2, wherein the silicon powder is N-type silicon powder containing phosphorus or arsenic.

11. The method of manufacturing a polycrystalline solar cell panel according to claim 10, wherein a polycrystalline silicon film having a P-N junction is formed by sweeping plasma containing boron particles on a surface of a N-type silicon powder layer applied on the substrate.

12. The method of manufacturing a polycrystalline solar cell panel according to claim 2, wherein
the step of forming the silicon powder layer comprises:
forming a N-type silicon powder layer on the substrate by applying N-type silicon powder containing phosphorus or arsenic; and
forming a P-type silicon powder layer by applying P-type silicon powder containing boron on the N-type silicon powder layer.

13. A polycrystalline solar cell panel obtained using the method according to claim 2.
